(19) United States
(12) Patent Application Publication
(10) Pub. No.: US 2006/0067052 A1
(43) Pub. Date: Mar. 30, 2006

(54) Liquid cooling system

(76) Inventors: David J. Llapitan, Tacoma, WA (US); Michael G. Berktold, DuPont, WA (US); Alan W. Tate, Puyallup, WA (US)

Correspondence Address: INTEL CORPORATION, P.O. BOX 5326, SANTA CLARA, CA, 95056-5326, US

(21) Appl. No.: 10/954,912

(22) Filed: Sep. 30, 2004

(51) Int. Cl. H05K 7/20

(52) U.S. Cl. 361/700; 165/80.4

(57) ABSTRACT

In some embodiments, a multi-processor system board has at least a first processor installed on the system board and at least a first liquid cooling system configured to provide dedicated cooling for the first processor. A second processor may be installed on the system board and a second liquid cooling system may be configured to provide dedicated cooling for the second processor. In some examples, a liquid cooling system includes a tank, a first heat exchanger attached to a first side of the tank, and a second heat exchanger attached to a second side of the tank opposite to the first side of the tank. Other embodiments are disclosed and claimed.

The invention relates to liquid cooling systems and more particularly to liquid cooling systems for electronic components, and methods related thereto.

### BACKGROUND AND RELATED ART

A liquid cooling system is described in U.S. Pat. No. 6,749,012, assigned in common with the present application. Referring to FIG. 1, a liquid cooling system 10 for a processor-based system may include a housing 12 that houses a heat exchanger core 36 and a liquid pump (not shown in FIG. 1). Secured to the housing 12 is a fan assembly 26 including a fan 14. The fan 14 is positioned over an opening in the housing 12 to provide air cooling of liquid inside a heat exchanger core 36. The heat exchanger core 36 is defined in part by opposed faces separated a given amount to define a thickness direction. The fan 14 may be coupled to an electrical potential through a connector 18. The liquid pump may be coupled to an electrical potential through a connector 16. A portion 28 of the housing 12 may comprise a tank or reservoir for the pumped, cooling liquid.

The cooled liquid, passing out of the housing 12, may pass through a pipe 20b to a processor cold plate 22 and then back through return pipe 20a. A processor 24 of a processor-based system may be in thermal contact with the cold plate 22.

Referring to FIG. 2, a processor-based system 40 may include the processor 24 thermally coupled to the cooling system 10. The processor 24 may be electrically coupled to an interface 42, such as a bridge. The interface 42 is coupled to a memory 44 and a bus 46. The bus 46 may, in turn, be coupled to another interface 48, such as a bridge. The interface 48 may also be coupled to a hard disk drive 50 in one embodiment.

In some embodiments, the interface 48 may provide electrical signals to the cooling system 10 to control its operation. For example, based on the performance or temperature of the processor 24, additional cooling may be provided under control of the interface 48. Thus, signals may be provided to the connectors 18 and 16 to control the fan 14 and pump 30 to achieve a desired processor 24 temperature.

Other details of the construction and operation of the liquid cooling system 10 may be had with reference to the '012 patent.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the invention.

FIG. 1 is a perspective view of a liquid cooling system;

FIG. 2 is a schematic depiction of a liquid cooling system for a processor-based device;

FIG. 3 is a perspective view of a liquid cooling apparatus in accordance with some embodiments of the invention;

FIG. 4 is a top, schematic view of the liquid cooling apparatus from FIG. 3;

FIG. 5 is a side, schematic view of the liquid cooling apparatus from FIG. 3;

FIG. 6 is a front, schematic view of the liquid cooling apparatus from FIG. 3;

FIG. 7 is a perspective, cut-away view of the liquid cooling apparatus from FIG. 3;

FIG. 8 is a side, cross sectional view of the liquid cooling apparatus from FIG. 3;

FIG. 9 is a block diagram of a computer system in accordance with some embodiments of the invention;

FIG. 10 is a block diagram of another computer system in accordance with some embodiments of the invention; and

FIG. 11 is a perspective view of two liquid cooling systems, in accordance with some embodiments of the invention.

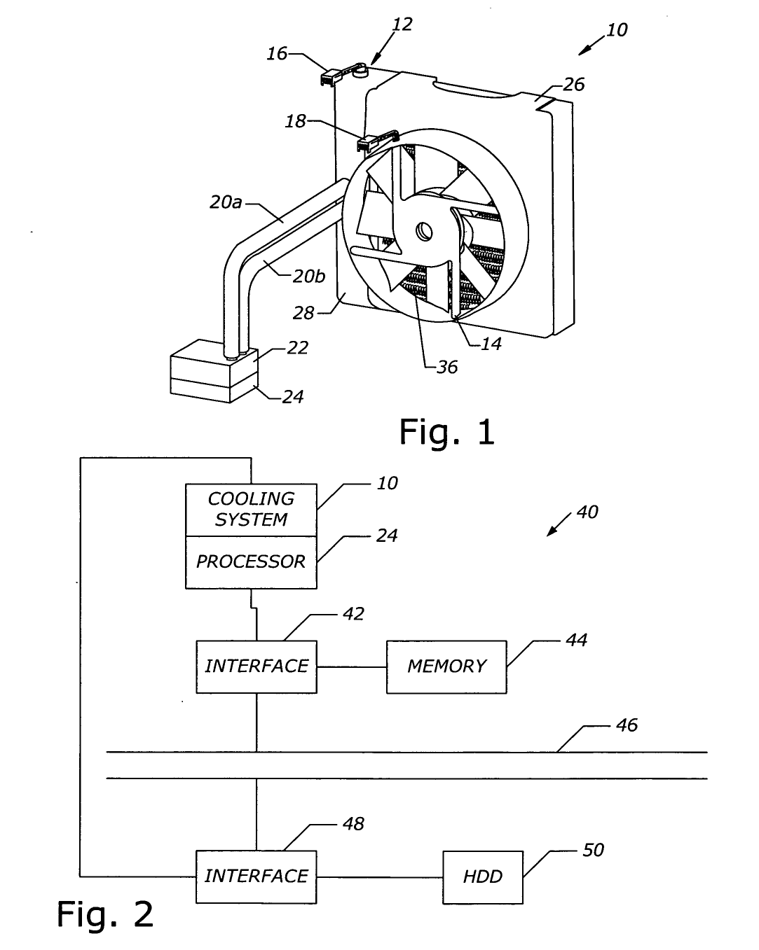

### DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

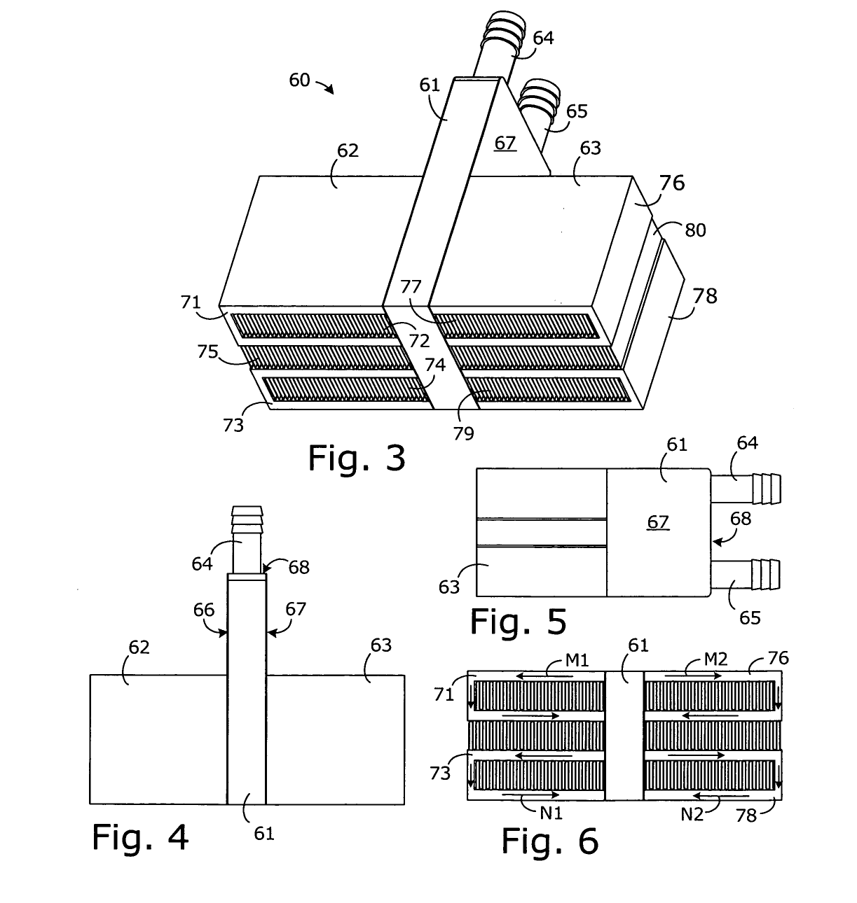

With reference to FIGS. 3-8, a liquid cooling apparatus 60 includes a tank 61 disposed between two heat exchangers 62 and 63. Two primary fluid ports, nominally a primary inlet port 64 and a primary outlet port 65, are provided on the tank 61. As illustrated, the tank 61 is a box-shaped container with substantially flat side walls, although the tank 61 may be readily configured with other shapes as may be necessary or desirable for particular applications.

In some embodiments of the invention, the liquid cooling apparatus 60 includes the tank 61 with the first heat exchanger 62 attached to a first side 66 of the tank 61 and the second heat exchanger 63 attached to a second side 67 of the tank 61 opposite to the first side 66 of the tank 61. The primary inlet 64 and the primary outlet 65 are attached to a third side 68 of the tank, the third side 68 being located between and attached to both the first and second side walls, 66, 67. For example, the heat exchangers 62, 63 and or ports 64, 65 may be attached to the tank 61 with a fluid seal by welding, brazing, soldering, adhering, forming a metallurgical bond, or other known or hereinafter discovered suitable attachment techniques. In some embodiments, the tank 61 may be substantially centrally located between the first and second heat exchangers 62, 63.

Advantageously, the tank 61 located between the two heat exchangers 62, 63 may provide redundancy in the cooling capability. For example, if the flow in one of the two heat exchangers 62, 63 becomes restricted, the non-restricted heat exchanger may continue to function properly. The properly functioning heat exchanger may provide adequate cooling on its own or may extend the operating time of the system prior to servicing. Another potential benefit of a centrally located tank 61 is that the inlet and outlet ports on the tank 61 may be more likely to be located near the processor, which may simplify the tube routing.

The heat exchangers 62, 63 may have any of a number of suitable configurations as may be necessary or desirable for a particular application. As illustrated, the first heat exchanger 62 includes a first U-shaped duct 71 defining a first fluid channel with a first folded fin heat sink 72 disposed in the legs of the first duct 71. The first heat exchanger 62 further includes a second U-shaped duct 73 defining a second fluid channel with a second folded fin heat sink 74 disposed in the legs of the first duct 73. A third folded fin heat sink 75 is attached between the first and second ducts 71, 73. The second heat exchanger is similarly configured with a first U-shaped duct 76 with a corresponding first folded fin heat sink 77, a second U-shaped duct 78 with a corresponding second folded fin heat sink 79, and a third folded fin heat sink 80 attached between the two ducts 76, 78. Although two ducts are presented in this example, more or less may be provided depending on the particular application.

The tank 61 is in fluid communication with both the first and second heat exchangers 62, 63. For example, with reference to FIG. 8, the tank 61 may include a first fluid outlet 81 and first fluid inlet 82 on the first side 66 of the tank 61 and a second fluid outlet (not shown but, e.g. similarly situated) and a second fluid inlet (not shown but, e.g. similarly situated) on the second side 67 of the tank, aligned with the respective first ducts 71, 76 of the first and second heat exchangers 62, 63.

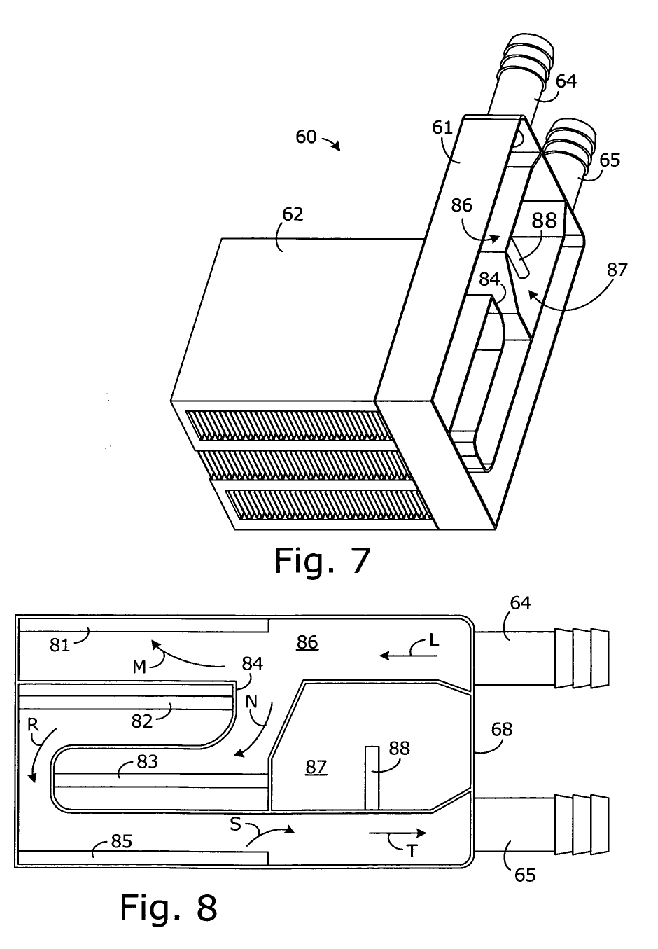

In some embodiments, the tank 61 further includes a third fluid outlet 83 on the first side 66 of the tank 61, a fourth fluid outlet (not shown, but e.g. similarly situated) on the second side 67 of the tank, and baffling 84 inside the tank (see FIG. 7) and arranged to distribute fluid between the first 81 and second and third 83 and fourth fluid outlets. The tank 61 may further include a fourth fluid inlet 85 on the first side 66 of the tank 61 and a fourth fluid inlet (not shown but, e.g. similarly situated) on the second side 67 of the tank 61. For example, the third and fourth fluid outlets and inlets may be aligned with the respective second ducts 73, 78 of the first and second heat exchangers 62, 63

In some embodiments, the tank 61 includes both a distribution tank 86 and a reservoir tank 87 in a same housing. For example, in addition to defining flow paths, the baffling 84 inside the tank 61 may define a separate chamber for the reservoir tank 87 in the same housing as the distribution tank 86 (see FIGS. 7-8).

In some embodiments, a hollow tube 88 may be provided inside the reservoir tank 87. The tube 88 is in fluid communication with the distribution tank 86 and allows air or gas bubbles to escape the distribution system into the reservoir tank 87. The reservoir tank 87 may initially be filled with reserve fluid that can be drawn into the distribution tank 86 when fluid is lost from the distribution system due to, for example, leaks or evaporation. The opening of the tube 88 is relatively centrally positioned in the reservoir tank 87 so that the tank may be oriented either horizontally or vertically while still keeping the opening submerged in the reservoir tank 87, even after substantial bubbles have accumulated in the reservoir tank 87. For example, as long as the contained gas bubble does not grow larger than roughly half of the size of the reservoir tank 87, the tube 88 will be in the reservoir liquid and the gas bubble will be trapped, thus reducing the possibility of a dry pump condition where no liquid flows.

In some embodiments, the reservoir tank 87 may also be considered an expansion tank, allowing fluid expansion into the reservoir tank 87. Advantageously, the tank 61 incorporating both the distribution tank 86 and the reservoir/bubble containment/expansion tank 87 in the same housing reduces or eliminates the need for an additional tank or tank(s) elsewhere in the system, thereby simplifying assembly and reducing cost.

A method of constructing a liquid cooling apparatus, according to some embodiments of the invention, includes providing a tank 61, attaching a first heat exchanger 62 to a first side 66 of the tank 61, attaching a second heat exchanger 63 to a second side 67 of the tank 61 opposite to the first side 66 of the tank 61, and providing fluid communication between the tank 61 and both the first and second heat exchangers 62, 63. The method may further include locating the tank 61 substantially central between the first and second heat exchangers 62, 63. Some embodiments may further involve receiving a fluid in the tank 61, and distributing the fluid to a plurality of fluid outlets on both the first and second sides 66, 67 of the tank 61. Some examples include providing baffling 84 inside the tank 61 to define a plurality of flow paths for the fluid. Some examples include partitioning the tank 61 into both a distribution tank 86 and a reservoir tank 87.

In operation, with a suitable fluid circulating pump, the liquid cooling apparatus 60 may operate as follows. With reference to FIGS. 6 and 8, fluid received at the primary inlet 64 enters the tank 61 flowing in the direction indicated by arrow L. The baffling 84 splits the fluid into two flow paths indicated by arrows M and N. The flow path M exits the tank through the respective first and second fluid outlets on both the first and second sides of the tank 61 and enters the respective first ducts 71, 76. Fluid from flow path M flows through the heat exchangers 62, 63 along respective flow paths indicated by arrows M1 and M2. The flow path N exits the tank through the respective third and fourth fluid outlets on both the first and second sides of the tank 61 and enters the respective second ducts 73, 78. Fluid from flow path N flows through the heat exchangers 62, 63 along respective flow paths indicated by arrows N1 and N2. A total of four cooling channels (M1, M2, N1, and N2) are provided through the heat exchangers 62, 63.

The flow paths M1 and M2 re-enter the tank through the respective first and second fluid inlets on both the first and second sides of the tank 61 and merge into flow path R. The flow paths N1 and N2 re-enter the tank through the respective third and fourth fluid inlets on both the first and second sides of the tank 61 and merge into flow path S. The flow paths R and S merge and fluid exits the tank from the primary outlet 65 along the flow path T.

Advantageously, the baffles 84 force the fluid to four cooling channels, two on each side, where the fluid may be cooled by the fins of the heat exchangers 62, 63, optionally supplemented by air flowing though the fins of the heat exchanger as may be necessary or desirable. The baffles 84 also completely separate the incoming flow paths L, M, and N from the outgoing flow paths R, S, and T. In some embodiments, more or less cooling channels may be provided (e.g. one on each side, or three or more on each side).

Another aspect of some embodiments of the invention involves utilizing the tank 61 in a first dedicated liquid cooling system for a first processor of a multi-processor computer system, and utilizing a second dedicated liquid cooling system for a second processor of the multi-processor computer system. In some examples, the first and second processors are both located on a same system board of the multi-processor system.

With reference to FIG. 9, a system includes a multi-processor system board 90 with at least a first processor 92 installed on the system board 90 and at least a first liquid cooling system 96 configured to provide dedicated cooling for the first processor 92. The system may further include a second processor 94 installed on the system board 90 and a second liquid cooling system 98 configured to provide dedicated cooling for the second processor 94. For example, the first and or second liquid cooling system(s) 96, 98 may include a tank, a first heat exchanger attached to a first side of the tank, and a second heat exchanger attached to a second side of the tank opposite to the first side of the tank, wherein the tank is in fluid communication with both the first and second heat exchangers (e.g. as described in connection with FIGS. 3-8 above). The tank may include both a distribution tank and a reservoir tank in a same housing. The tank may be substantially centrally located between the first and second heat exchangers. The tank may include baffling inside the tank to define a plurality of flow paths.

Some conventional liquid cooling systems for multi-processor system boards utilize a single heat exchanger shared between the processors. Providing a dedicated liquid cooling system for each processor in a multi-processor system may provide advantages as compared to current technology that utilizes a heat exchanger which may be shared between two or more processors. For example, independently operating liquid cooling systems provide redundancy, such that if one liquid cooling system fails, the others continue to operate. Also, a single shared heat exchanger may have more complicated tube routing requirements. Utilizing multiple dedicated liquid cooling systems may shorten the length of tubing required and simplify the tube routing, particularly when utilizing the liquid cooling apparatus of FIGS. 3-8.

Often times, a multi-processor system is initially configured with less than full capacity (e.g. only a single processor of a dual-processor system is installed). A further potential advantage of utilizing multiple, dedicated liquid cooling systems as opposed to a shared liquid cooling system is that the initial cost of the system may be reduced. The extra capacity of the shared liquid cooling system comes at an extra cost (sometimes including multiple cold plates and associated tubing), which is not needed until the second processor is installed (and is completely unnecessary if the second processor is never installed). By shipping the multi-processor system with only as many dedicated liquid cooling systems as needed for each initially installed processor, the customer may realize cost savings in terms of lower part counts, less shipping weight, and a smaller, less costly liquid cooling system.

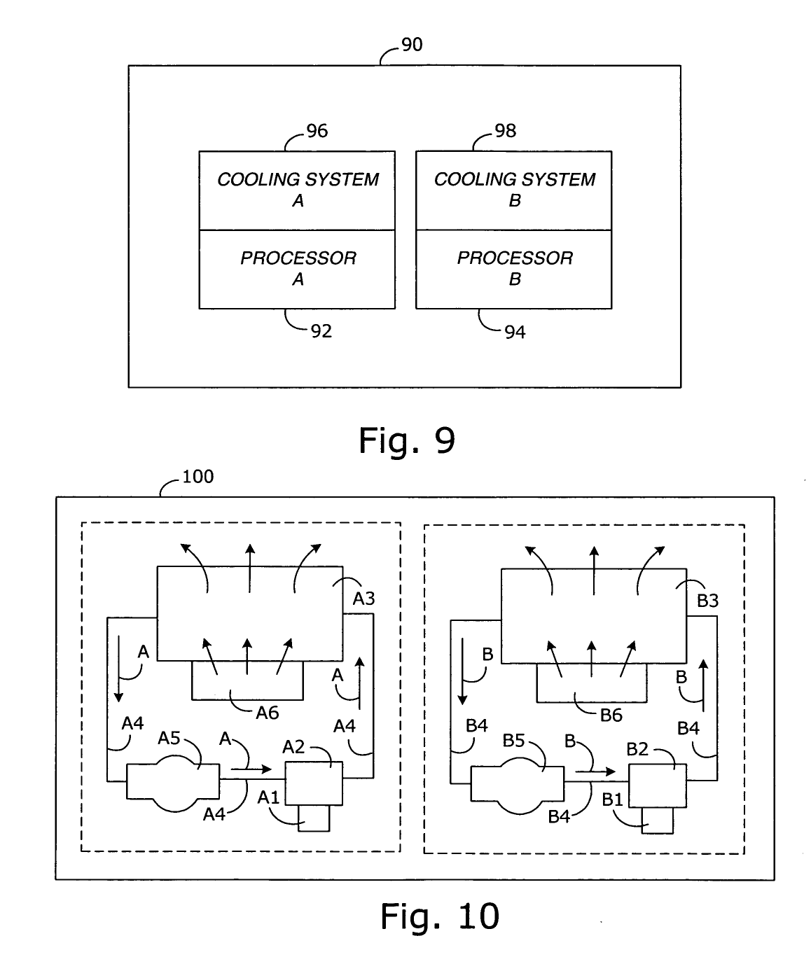

With reference to FIG. 10, a liquid cooled system 100 includes a heat source A1 (e.g. a processor or other electronic device). A cold plate A2 is mechanically and thermally coupled to the heat source A1. The cold plate A2 is in liquid communication with a heat exchanger (HEX) A3 (e.g. the liquid cooling apparatus of FIGS. 3-8). Cooling liquid is circulated from the cold plate A2 to the HEX A3 and back again to provide a cooling cycle. For example, the cold plate A2 may be connected in a loop to the HEX A3 by tubing A4. A pump A5 may be provided in line with one branch of the tubing A4 to circulate the cooling liquid contained in the tubing A4 (e.g. in the direction of arrows A). The system 100 may include one or more optional fan(s) A6 to provide air flow for the HEX A3 and/or the cold plate A2.

The liquid cooled system 100 further includes an optional additional heat source B1 (e.g. a second processor in a dual-processor system). A cold plate B2 is mechanically and thermally coupled to the heat source B1. The cold plate B2 is in liquid communication with a HEX B3 (e.g. the liquid cooling apparatus of FIGS. 3-8). Cooling liquid is circulated from the cold plate B2 to the HEX B3 and back again to provide a cooling cycle. For example, the cold plate B2 may be connected in a loop to the HEX B3 by tubing B4. A pump B5 may be provided in line with one branch of the tubing B4 to circulate the cooling liquid contained in the tubing B4 (e.g. in the direction of arrows B). The system 100 may include optional fan(s) B6 to provide air flow for the HEX B3 and/or the cold plate B2.

In some embodiments, the tubes A4, B4 are flexible, easily routed, substantially resistant to laceration and kinking, have an extremely low water vapor transmission rate, and can be manufactured at low cost. The tubes may, for example be formed of one or more of the following materials: FEP, PVDF, ETFE, PTFE or a fluoro-elastomer, such as a fluorinated EPDM rubber (e.g., Viton, available from DuPont). The tubes may be formed by extrusion, for example. The tubes may be formed of the materials mentioned above in combination with other materials. For example, a co-extrusion process may be employed to produce the tubes 48, 50 so as to have two or more layers, each of which is formed of a different material. In some embodiments, the tubes may have two layers including an inner layer formed of one of FEP, PVDF, ETFE, PTFE or a fluoro-elastomer and an outer layer of nylon, for example. Tube-in-tube construction may also be employed for each of the tubes.

Forming the tubes of one or more of FEP, PVDF, ETFE, PTFE or a fluoro-elastomer is particularly advantageous in that such materials provide an extremely low water vapor transmission rate. This characteristic, either alone or in combination with other features of the cooling system described herein, may allow the cooling system to operate properly for an extended period (e.g., several years), without excessive loss of coolant through evaporation, and without servicing.

The tubes may be arranged in a parallel course from the heat exchanger to the cold plate, and may be in contact with each other (e.g., attached or bound to each other) substantially entirely along that course. This may facilitate convenient routing of the tubes. For example, the adjacent location of the outlet port and the inlet port of the heat exchanger in FIGS. 3-8 may facilitate convenient parallel routing of the tubes to a cold plate having co-located inlet and outlet ports. Also, in some applications the centrally located tank may place the inlet and outlet ports closer to the device to be cooled, thereby providing simpler and shorter routing for the tubes.

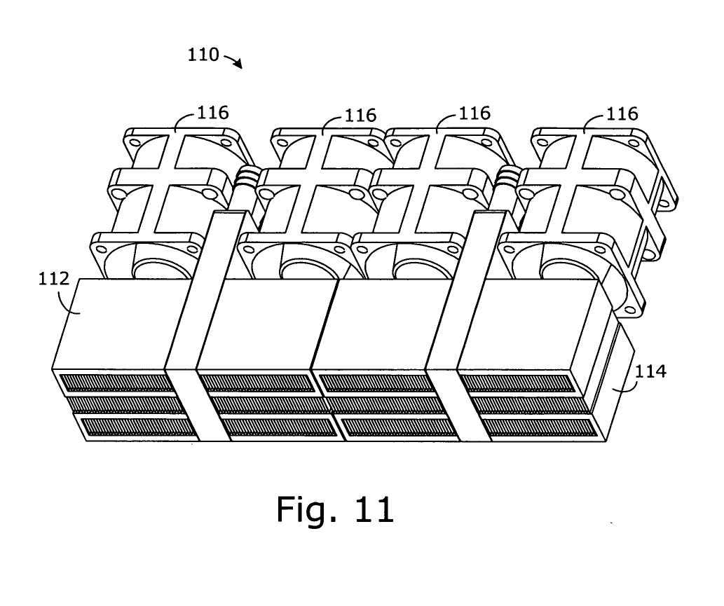

With reference to FIG. 11, a liquid cooling system 110 includes a first liquid cooling device 112 and an optional second liquid cooling device 114, each constructed substantially as described above in connection with FIGS. 3-8. Each of the devices 112 and 114 may be configured to have one unit (1 U) of standard rack height to provide a 1 U liquid cooling heat exchanger with integrated central distribution and reservoir tanks. Each liquid cooling device 112, 114 has two associated fans 116. For a 1 U system, preferably the fans are 40×40 mm high performance fans. The 1 U liquid cooling devices 112, 114 may be utilized in a rack mount server system. For example, for a dual-processor system board, the first liquid cooling device 112 and associated fans 116 may be part of a dedicated liquid cooling system for one processor. If both processors are installed on the dual-processor board, the second liquid cooling device 112 and associated fans 116 may be part of a dedicated liquid cooling system for the second processor. The two cooling devices 112, 114 may installed side-by-side, as illustrated. The centrally located inlet and outlet ports may provide short and direct tube routing to the respective cold plates for each of the two processors.

The foregoing and other aspects of the invention are achieved individually and in combination. The invention should not be construed as requiring two or more of such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

What is claimed is:

1. An apparatus, comprising:
a tank;
a first heat exchanger attached to a first side of the tank; and
a second heat exchanger attached to a second side of the tank opposite to the first side of the tank, wherein the tank is in fluid communication with both the first and second heat exchangers.

2. The apparatus of claim 1, wherein the tank comprises a first fluid outlet and first fluid inlet on the first side of the tank and a second fluid outlet and a second fluid inlet on the second side of the tank.

3. The apparatus of claim 2, wherein the tank further comprises a third fluid outlet on the first side of the tank, a fourth fluid outlet on the second side of the tank, and baffling inside the tank and arranged to distribute fluid between the first and second and third and fourth fluid outlets.

4. The apparatus of claim 3, wherein the tank further comprises a fourth fluid inlet on the first side of the tank and a fourth fluid inlet on the second side of the tank.

5. The apparatus of claim 1, wherein the tank comprises both a distribution tank and a reservoir tank in a same housing.

6. The apparatus of claim 1, wherein the tank is substantially centrally located between the first and second heat exchangers.

7. The apparatus of claim 6, wherein the tank comprises both a distribution tank and a reservoir tank in a same housing.

8. The apparatus of claim 1, wherein the tank comprises a substantially box-shaped housing with substantially flat sides, wherein the tank is substantially centrally located between the first and second heat exchangers, the tank further comprising:
a primary fluid inlet positioned on a third side of the tank; and
a primary fluid outlet positioned on the third side of the tank, wherein the third side of the tank is attached between the first and second sides of the tank;
a first fluid outlet and first fluid inlet on the first side of the tank;
a second fluid outlet and a second fluid inlet on the second side of the tank;
a third fluid outlet and third fluid inlet on the first side of the tank;
a fourth fluid outlet and a fourth fluid inlet on the second side of the tank; and
baffling inside the tank and arranged to define respective flow paths from the primary fluid inlet to the first, second, third and fourth fluid outlets and from the first, second, third and fourth fluid inlets to the primary fluid outlet.

9. The apparatus of claim 8, wherein the baffling is further arranged to provide a reservoir tank inside the tank.

10. A method, comprising:
providing a tank;
attaching a first heat exchanger to a first side of the tank;
attaching a second heat exchanger to a second side of the tank opposite to the first side of the tank; and
providing fluid communication between the tank and both the first and second heat exchangers.

11. The method of claim 10, further comprising:
locating the tank substantially central between the first and second heat exchangers.

12. The method of claim 10, further comprising:
receiving a fluid in the tank; and
distributing the fluid to a plurality of fluid outlets on both the first and second sides of the tank.

13. The method of claim 12, further comprising:
providing baffling inside the tank to define a plurality of flow paths for the fluid.

14. The method of claim 10, further comprising:
partitioning the tank into both a distribution tank and a reservoir tank.

15. The method of claim 10, further comprising:
utilizing the tank in a first dedicated liquid cooling system for a first processor of a multi-processor computer system; and
utilizing a second dedicated liquid cooling system for a second processor of the multi-processor computer system.

16. The method of claim 15, wherein the first and second processors are both located on a same system board of the multi-processor system.

17. A system, comprising:
a multi-processor system board;
at least a first processor installed on the system board; and
at least a first liquid cooling system configured to provide dedicated cooling for the first processor.

18. The system of claim 17, further comprising:
a second processor installed on the system board; and
a second liquid cooling system configured to provide dedicated cooling for the second processor.

19. The system of claim 17, wherein the first liquid cooling system comprises:
a tank;
a first heat exchanger attached to a first side of the tank; and
a second heat exchanger attached to a second side of the tank opposite to the first side of the tank, wherein the tank is in fluid communication with both the first and second heat exchangers.

20. The system of claim 19, wherein the tank comprises both a distribution tank and a reservoir tank in a same housing.

21. The system of claim 19, wherein the tank is substantially centrally located between the first and second heat exchangers.

22. The system of claim 19, wherein the tank includes baffling inside the tank to define a plurality of flow paths.
